(19) United States
(12) Patent Application Publication
(10) Pub. No.: US 2026/0086467 A1
(43) Pub. Date: Mar. 26, 2026

(54) EXPOSURE METHOD AND ELECTRONIC DEVICE MANUFACTURING METHOD

(71) Applicant: Gigaphoton Inc., Oyama-shi (JP)

(72) Inventor: Koichi FUJII, Oyama-shi (JP)

(73) Assignee: Gigaphoton Inc., Oyama-shi (JP)

(21) Appl. No.: 19/404,850

(22) Filed: Dec. 1, 2025

Related U.S. Application Data
(63) Continuation of application No. PCT/JP2023/028011, filed on Jul. 31, 2023.

(51) Int. Cl. G03F 7/00; G03F 7/20

(52) U.S. Cl. CPC G03F 7/70575; G03F 7/2022; G03F 7/70525; G03F 7/70266

(57) ABSTRACT

An exposure method includes a first step of setting a wavelength of a first pulse laser beam that scans a first scan field of a first semiconductor wafer to a first pattern that changes according to an in-field position along a scanning direction in the first scan field and setting a wavelength of a second pulse laser beam that scans a second scan field of the first semiconductor wafer to a second pattern that changes according to an in-field position along a scanning direction in the second scan field and that is different from the first pattern based on measurement results regarding positional deviation of exposure results by pre-exposure using an exposure apparatus, and a second step of scanning the first scan field with the first pulse laser beam and then scanning the second scan field with the second pulse laser beam using the exposure apparatus.

### CROSS-REFERENCE TO RELATED APPLICATIONS

The present application is a continuation application of International Application No. PCT/JP2023/028011, filed on Jul. 31, 2023, the entire contents of which are hereby incorporated by reference.

### BACKGROUND

### 1. Technical Field

The present disclosure relates to an exposure method and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Patent Application Publication No. 2007/0273851
Patent Document 2: U.S. Patent Application Publication No. 2006/0114437
Patent Document 3: Japanese Unexamined Patent Application Publication No. 2009-231564
Patent Document 4: U.S. Patent Application Publication No. 2010/0092881
Patent Document 5: U.S. Patent Application Publication No. 2012/0154806
Patent Document 6: U.S. Patent Application Publication No. 2011/0216294

### SUMMARY

An exposure method according to one aspect of the present disclosure includes a first step and a second step. The first step includes setting a wavelength of a first pulse laser beam that scans a first scan field of a first semiconductor wafer to a first pattern that changes according to an in-field position along a scanning direction in the first scan field, and setting a wavelength of a second pulse laser beam that scans a second scan field of the first semiconductor wafer to a second pattern that changes according to an in-field position along a scanning direction in the second scan field and that is different from the first pattern, based on measurement results regarding positional deviation of exposure results by pre-exposure using an exposure apparatus. The second step includes scanning the first scan field with the first pulse laser beam and then scanning the second scan field with the second pulse laser beam using the exposure apparatus.

An electronic device manufacturing method according to one aspect of the present disclosure includes a first step and a second step. The first step includes setting a wavelength of a first pulse laser beam that scans a first scan field of a first semiconductor wafer to a first pattern that changes according to an in-field position along a scanning direction in the first scan field, and setting a wavelength of a second pulse laser beam that scans a second scan field of the first semiconductor wafer to a second pattern that changes according to an in-field position along a scanning direction in the second scan field and that is different from the first pattern, based on measurement results regarding positional deviation of exposure results by pre-exposure using an exposure apparatus. The second step includes scanning the first scan field with the first pulse laser beam and then scanning the second scan field with the second pulse laser beam using the exposure apparatus, to manufacture an electronic device.

### BRIEF DESCRIPTION OF THE DRAWINGS

Some embodiments of the present disclosure will be described below, by way of example only, with reference to the accompanying drawings.

FIG. 1 schematically illustrates a configuration of an exposure system in a comparative example.

FIG. 2 schematically illustrates the configuration of the exposure system in the comparative example.

FIG. 3 illustrates how a position of a scan field of a semiconductor wafer changes relative to a position of a beam cross section of a pulse laser beam together with FIG. 4 and FIG. 5.

FIG. 4 illustrates how a position of a scan field of a semiconductor wafer changes relative to a position of a beam cross section of a pulse laser beam together with FIG. 3 and FIG. 5.

FIG. 5 illustrates how a position of a scan field of a semiconductor wafer changes relative to a position of a beam cross section of a pulse laser beam together with FIG. 3 and FIG. 4.

FIG. 6 schematically illustrates a configuration of an exposure system in a first embodiment.

FIG. 7 is a flowchart illustrating processing of wavelength correction by the first embodiment.

FIG. 8 illustrates an entire pre-exposure wafer or semiconductor wafer and details of a part thereof.

FIG. 9 is a flowchart illustrating details of processing for calculating a change amount of wavefront aberration relative to a change in wavelength.

FIG. 10 is a flowchart illustrating details of processing for calculating a change amount of positional deviation relative to a change in wavefront aberration.

FIG. 11 is a flowchart illustrating details of processing for calculating a wavelength correction amount corresponding to a measured overlay error.

FIG. 12 illustrates a method for converting a subscript i that specifies a semiconductor wafer and a subscript j that specifies a scan field to elapsed time t from exposure start.

FIG. 13 illustrates a wavelength correction amount corresponding to a measured overlay error being plotted.

FIG. 14 illustrates an example of a model obtained by fitting a wavelength correction amount to an exponential function.

FIG. 15 illustrates examples of a model created for each subscript k.

FIG. 16 illustrates examples of a change pattern of a wavelength of a pulse laser beam that scans a scan field.

FIG. 17 is a flowchart illustrating processing of wavelength correction by a second embodiment.

FIG. 18 illustrates a method for converting a subscript i that specifies a semiconductor wafer and a subscript j that specifies a scan field to elapsed time t from exposure start.

FIG. 19 illustrates a measured overlay error being plotted.

FIG. 20 illustrates an example of a model obtained by fitting an overlay error to an exponential function.

FIG. 21 is a flowchart illustrating details of processing for calculating a wavelength correction amount for all semiconductor wafers.

FIG. 22 illustrates examples of a wavelength correction amount determined in S704.

FIG. 23 illustrates examples of a change pattern of a wavelength of a pulse laser beam that scans a scan field.

### DESCRIPTION OF EMBODIMENTS

### <Contents>

1. Comparative Example
   1.1 Exposure System
   1.2 Exposure Apparatus 200
      1.2.1 Configuration
      1.2.2 Operation
   1.3 Laser Apparatus 100
      1.3.1 Configuration
      1.3.2 Operation
   1.4 Line Narrowing Module 14
      1.4.1 Configuration
      1.4.2 Operation
   1.5 Scan Exposure
   1.6 Problem of Comparative Example
2. Exposure System that Generates Chromatic Aberration
   2.1 Configuration
   2.2 Operation
      2.2.1 Wavefront Aberration W
      2.2.2 Main Flow
      2.2.3 Calculation of dZₙₚ/dλ
      2.2.4 Calculation of ∂E_{g}/∂Zₙ
      2.2.5 Calculation of Wavelength Correction Amount Δλᵢⱼₖ corresponding to Measured Overlay Error D_{ijkpg}
      2.2.6 Calculation of Wavelength Correction Amount Δλᵢⱼₖ for All Semiconductor Wafers WF
      2.2.7 Relationship between Wavelength Fluctuation in Scan Field SF and Wavelength Fluctuation corresponding to Elapsed Time t
   2.3 Effect
3. Exposure System that Creates Model of Overlay Error D_{ijkpg}
   3.1 Operation
      3.1.1 Main Flow
      3.1.2 Determination of Overlay Error D_{ijkpg} for All Semiconductor Wafers WF
      3.1.3 Calculation of Wavelength Correction Amount Δλᵢⱼₖ for All Semiconductor Wafers WF
   3.2 Effect
4. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

### 1.1 Exposure System

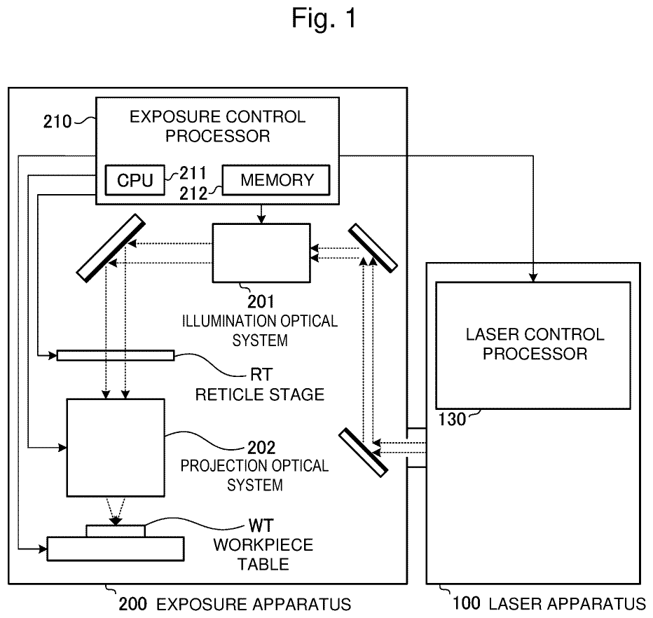

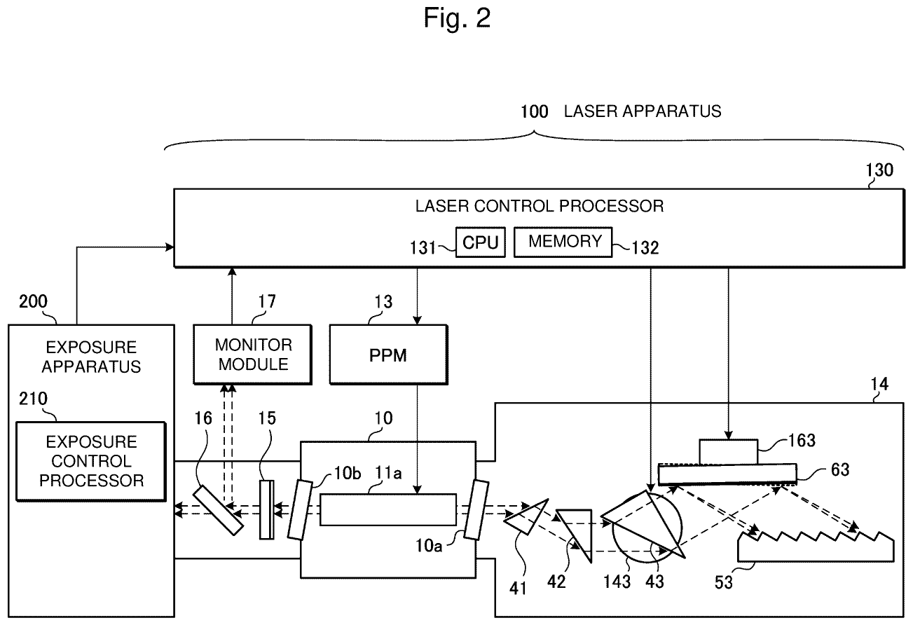

FIGS. 1 and 2 schematically illustrate a configuration of an exposure system in a comparative example. The comparative example of the present disclosure is an example recognized by the applicant as known only by the applicant, and is not a publicly known example admitted by the applicant.

The exposure system includes a laser apparatus 100 and an exposure apparatus 200. In FIG. 1, the laser apparatus 100 is illustrated in a simplified manner. In FIG. 2, the exposure apparatus 200 is illustrated in a simplified manner.

The laser apparatus 100 includes a laser control processor 130. The laser apparatus 100 is configured to output a pulse laser beam toward the exposure apparatus 200.

### 1.2 Exposure Apparatus 200

### 1.2.1 Configuration

As illustrated in FIG. 1, the exposure apparatus 200 includes an illumination optical system 201, a projection optical system 202, and an exposure control processor 210.

The illumination optical system 201 illuminates a reticle pattern of a non-illustrated reticle disposed on a reticle stage RT with the pulse laser beam incident from the laser apparatus 100.

The pulse laser beam having transmitted through the reticle is imaged on a non-illustrated workpiece disposed on a workpiece table WT by reduced projection through the projection optical system 202. The workpiece is a photosensitive substrate such as a semiconductor wafer on which a resist film is applied.

The exposure control processor 210 is a processing device including a memory 212 in which a control program is stored and a CPU (central processing unit) 211 configured to execute the control program. The exposure control processor 210 is specially configured or programmed to execute various kinds of processing included in the present disclosure. The exposure control processor 210 collectively controls the exposure apparatus 200 and transmits and receives various kinds of data and various signals to and from the laser control processor 130.

### 1.2.2 Operation

The exposure control processor 210 sets various parameters related to exposure conditions and controls the illumination optical system 201 and the projection optical system 202.

The exposure control processor 210 transmits data of a wavelength target value and a trigger signal to the laser control processor 130. The laser control processor 130 controls the laser apparatus 100 in accordance with the data and the signal.

The exposure control processor 210 translates the reticle stage RT and the workpiece table WT in directions opposite to each other in synchronization. Accordingly, the workpiece is exposed to the pulse laser beam reflecting the reticle pattern.

Through such an exposure process, the reticle pattern is transferred to the semiconductor wafer. Thereafter, an electronic device can be manufactured through a plurality of processes.

### 1.3 Laser Apparatus 100

### 1.3.1 Configuration

As illustrated in FIG. 2, the laser apparatus 100 includes a laser chamber 10, a pulse power module (PPM) 13, a line narrowing module 14, an output coupling mirror 15, and a monitor module 17 in addition to the laser control processor 130. The line narrowing module 14 and the output coupling mirror 15 form an optical resonator.

The laser chamber 10 is disposed in an optical path of the optical resonator. The laser chamber 10 is provided with windows 10a and 10b.

The laser chamber 10 includes an electrode 11a and a non-illustrated electrode paired therewith inside, and further houses laser gas containing components of a laser medium. The laser medium is, for example, F₂, ArF, KrF, XeCl, or XeF.

The pulse power module 13 includes a non-illustrated switch and is connected to a non-illustrated charger.

The line narrowing module 14 includes prisms 41 to 43, a grating 53, and a mirror 63. Details of the line narrowing module 14 will be described later.

The output coupling mirror 15 is formed of a partial reflective mirror. A beam splitter 16 that transmits a part of the pulse laser beam with a high transmittance and reflects the other part is disposed in an optical path of the pulse laser beam output from the output coupling mirror 15. The monitor module 17 is disposed in an optical path of the pulse laser beam reflected by the beam splitter 16.

The laser control processor 130 is a processing device including a memory 132 in which a control program is stored and a CPU 131 configured to execute the control program. The laser control processor 130 is specially configured or programmed to execute various kinds of processing included in the present disclosure.

### 1.3.2 Operation

The laser control processor 130 acquires the data of the wavelength target value from the exposure control processor 210. The laser control processor 130 transmits an initial setting signal to the line narrowing module 14 based on the wavelength target value. After pulse laser beam output is started, the laser control processor 130 receives wavelength measured data from the monitor module 17 and transmits a feedback control signal to the line narrowing module 14 based on the wavelength target value and the wavelength measured data.

The laser control processor 130 receives the trigger signal from the exposure control processor 210. The laser control processor 130 transmits an oscillation trigger signal based on the trigger signal to the switch of the pulse power module 13.

When having received the oscillation trigger signal from the laser control processor 130, the switch is turned on. When the switch is turned on, the pulse power module 13 generates high voltage in pulses from electric energy held in the charger. The pulse power module 13 applies the high voltage to the electrode 11a.

When the high voltage is applied to the electrode 11a, discharge occurs between the electrode 11a and the electrode paired therewith. The laser gas in the laser chamber 10 is excited by energy of the discharge and shifts to a high energy level. When the excited laser gas then shifts to a low energy level, light having a wavelength corresponding to the energy level difference is discharged.

The light generated in the laser chamber 10 is output to outside of the laser chamber 10 through the windows 10a and 10b. The light output through the window 10a is incident as a light beam on the line narrowing module 14. Of the light that has entered the line narrowing module 14, light having a wavelength near a desired wavelength is turned back by the line narrowing module 14 and is returned to the laser chamber 10.

The output coupling mirror 15 transmits and outputs a part of the light output through the window 10b and reflects the other part back to the laser chamber 10.

In this way, the light output from the laser chamber 10 reciprocates between the line narrowing module 14 and the output coupling mirror 15. This light is amplified every time it passes through a discharge space between the electrode 11a and the electrode paired therewith. The light subjected to laser oscillation and line narrowing in this manner is output as a pulse laser beam from the output coupling mirror 15 and enters the exposure apparatus 200.

### 1.4 Line Narrowing Module 14

### 1.4.1 Configuration

The prisms 41 to 43 are disposed in an optical path of the light beam output through the window 10a in an order from the smallest of the reference numerals. The prism 43 is rotatable about an axis perpendicular to a plane of FIG. 2 by a rotating stage 143.

The mirror 63 is disposed in an optical path of the light beam transmitted through the prisms 41 to 43. The mirror 63 is rotatable about an axis perpendicular to the plane of FIG. 2 by a rotating stage 163. The grating 53 is disposed in an optical path of the light beam reflected by the mirror 63.

### 1.4.2 Operation

The light beam output through the window 10a is expanded in beam width in a plane parallel to the plane of FIG. 2 by each of the prisms 41 to 43. The light beam transmitted through the prisms 41 to 43 is reflected by the mirror 63 and enters the grating 53.

The light beam incident on the grating 53 is reflected by a plurality of grooves of the grating 53 and is diffracted in a direction corresponding to the wavelength of the light. The grating 53 is disposed in Littrow arrangement such that an incident angle of the light beam incident from the mirror 63 onto the grating 53 coincides with a diffracting angle of diffracted light of a desired wavelength.

The mirror 63 and the prisms 41 to 43 reduce the beam width of the light beam returned from the grating 53 in the plane parallel to the plane of FIG. 2, and return the light beam to the inside of the laser chamber 10 through the window 10a.

The laser control processor 130 controls the rotating stages 143 and 163 via a non-illustrated driver. In accordance with rotation angles of the rotating stages 143 and 163, the incident angle of the light beam incident on the grating 53 changes, and the wavelength selected by the line narrowing module 14 changes.

### 1.5 Scan Exposure

A semiconductor wafer is exposed with a pulse laser beam for each section called a scan field SF. The scan field SF corresponds to a region where some of many semiconductor chips to be formed on the semiconductor wafer are formed, and a reticle pattern of one reticle is transferred by scanning of one time.

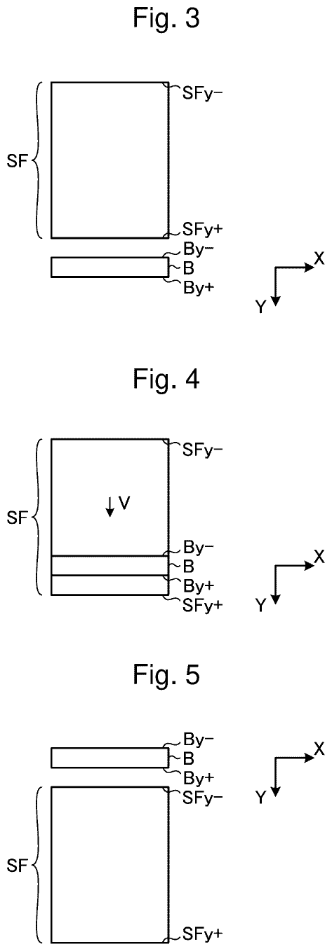

FIG. 3 to FIG. 5 illustrate how a position of the scan field SF of the semiconductor wafer changes relative to a position of a beam cross section B of the pulse laser beam. A direction in which the position of the scan field SF changes is defined as a Y axis direction, and a direction perpendicular to the Y axis direction is defined as an X axis direction.

A width in the X axis direction of the scan field SF corresponds to a width in the X axis direction of the beam cross section B of the pulse laser beam at a position of the workpiece table WT (see FIG. 1). A width in the Y axis direction of the scan field SF is larger than a width in the Y axis direction of the beam cross section B of the pulse laser beam at the position of the workpiece table WT.

A procedure of scanning and exposing each scan field SF in the Y axis direction with the pulse laser beam is performed in the order of FIG. 3, FIG. 4, and FIG. 5. First, as illustrated in FIG. 3, the workpiece table WT is positioned such that an end SFy+ of the scan field SF in a +Y direction is positioned at a predetermined distance in a −Y direction from a position of an end By− of the beam cross section B in the −Y direction. Then, the workpiece table WT is accelerated in the +Y direction so as to be a velocity V before the end SFy+ of the scan field SF in the +Y direction coincides with the position of the end By− of the beam cross section B in the −Y direction. As illustrated in FIG. 4, the scan field SF is exposed while the workpiece table WT is moved in the +Y direction such that the position of the scan field SF moves uniformly and linearly at the velocity V relative to the position of the beam cross section B. As illustrated in FIG. 5, when the workpiece table WT is moved such that the end SFy− of the scan field SF in the −Y direction passes by the position of the end By+ of the beam cross section B in the +Y direction, the scanning of the scan field SF ends.

### 1.6 Problem of Comparative Example

In manufacturing of an electronic device, a plurality of layers forming a semiconductor chip are exposed in an overlapped manner. In order to manufacture an electronic device that operates as designed, overlay accuracy of a few nanometers or less may be required. However, while successively exposing a plurality of scan fields SF or a plurality of semiconductor wafers, positional deviation of exposure results may occur due to temperature variations in the exposure apparatus 200, making it difficult to meet overlay accuracy requirements.

For example, the reticle arranged on the reticle stage RT may absorb a part of the pulse laser beam, causing a temperature of the reticle to rise. The reticle pattern drawn on the reticle is not uniform in the plane of the reticle, and the number of times of reciprocation of the pulse laser beam reflected multiple times on both sides of the reticle varies according to the pattern density, resulting in the temperature variations in the plane of the reticle and uneven expansion of the reticle. As a result, depending on elapsed time from exposure start and the position within the reticle plane, the positional deviation of the exposure results occurs.

In addition, an optical element included in the projection optical system 202 may absorb a part of the pulse laser beam, causing the temperature of the optical element to rise. Since diffracted light corresponding to settings of the illumination optical system 201 and the reticle pattern enters the projection optical system 202 and the diffracted light passes through a specific part of the projection optical system 202, temperature variations occur in the projection optical system 202, leading to uneven expansion and local changes in a refractive index. As a result, a path of a light ray passing through the projection optical system 202 changes, causing complex aberration, and depending on the elapsed time from the exposure start and the position within the beam cross section B, an imaging position shifts in an optical axis direction, causing a CD (critical dimension) to change, or the imaging position shifts in a direction perpendicular to an optical axis, causing the positional deviation of the exposure results.

Some embodiments described below are related to suppressing the positional deviation and the change of the CD that differ depending on the elapsed time from the exposure start and the position within the scan field SF.

### 2. Exposure System that Generates Chromatic Aberration

### 2.1 Configuration

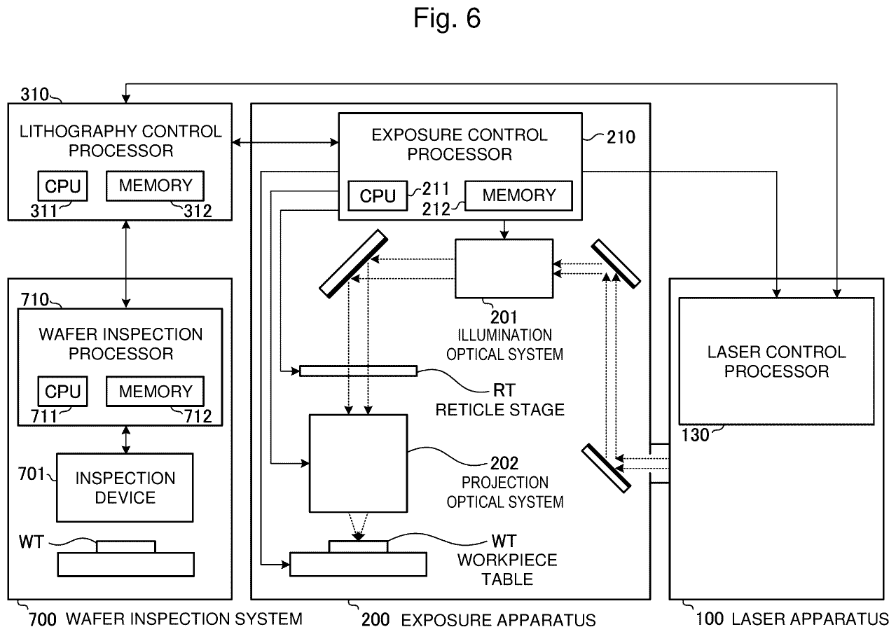

FIG. 6 schematically illustrates a configuration of an exposure system in a first embodiment. The exposure system includes a wafer inspection system 700 and a lithography control processor 310 in addition to the laser apparatus 100 and the exposure apparatus 200. The wafer inspection system 700 includes an inspection device 701 and a wafer inspection processor 710.

The lithography control processor 310 is a processing device including a memory 312 in which a control program is stored and a CPU 311 configured to execute the control program. The lithography control processor 310 is specially configured or programmed to execute various kinds of processing included in the present disclosure. The lithography control processor 310 is connected to each of the laser control processor 130, the exposure control processor 210, and the wafer inspection processor 710, and transmits and receives various kinds of data and various signals to and from these processors. The lithography control processor 310 may be connected to a plurality of laser control processors 130 included in a plurality of laser apparatuses 100 installed in a semiconductor factory, a plurality of exposure control processors 210 included in a plurality of exposure apparatuses 200, or a plurality of wafer inspection processors 710 included in a plurality of wafer inspection systems 700.

The inspection device 701 irradiates a non-illustrated semiconductor wafer disposed on the workpiece table WT with a laser beam, detects the reflected light or diffracted light, and measures the CD of a minute pattern formed on the semiconductor wafer or an overlay error, for example. Alternatively, the inspection device 701 may include a high-resolution scanning electron microscope (SEM) and measure the CD of the minute pattern by imaging the semiconductor wafer.

The wafer inspection processor 710 is a processing device including a memory 712 in which a control program is stored and a CPU 711 configured to execute the control program. The wafer inspection processor 710 is specially configured or programmed to execute various kinds of processing included in the present disclosure. The wafer inspection processor 710 is connected to each of the inspection device 701 and the lithography control processor 310 and transmits and receives various kinds of data and various signals to and from each of the inspection device 701 and the lithography control processor 310.

### 2.2 Operation

### 2.2.1 Wavefront Aberration W

Wavefront aberration W which is one of aberration expressing methods will be described. The projection optical system 202 is designed to convert spherical waves emanating from a point on the reticle into ideal spherical waves converging at a point on the semiconductor wafer. However, if for some reason they cannot be converted into the ideal spherical waves, the light may not converge at a single point, or it may converge at a position different from an intended point. Aberration expressed as the deviation from such an ideal sphere is the wavefront aberration W.

As indicated in a following equation, the wavefront aberration W can be expressed as a linear combination of a Zernike function series Zₙ.

$$W = {\sum }_{n} ( {a}_{n} {Z}_{n} ) = {a}_{1} {Z}_{1} + {a}_{2} {Z}_{2} + {a}_{3} {Z}_{3} + …$$

Here, an is a weighting coefficient for specifying the wavefront aberration W. A subscript n is a natural number from 1 to infinity, and the Zernike function series Zₙ is an infinite series of functions. A term aₙZₙ is called a Zernike term. In practice, the first 36, 49, 81, or 121 Zernike terms aₙZₙ are often used. By using the Zernike term aₙZₙ, it is possible to express complex aberration such as shifting a part of an image in the optical axis direction or in a direction perpendicular to the optical axis.

In the following description, display of the weighting coefficient aₙ is omitted, and the Zernike term aₙZₙ is simply represented as Zₙ.

### 2.2.2 Main Flow

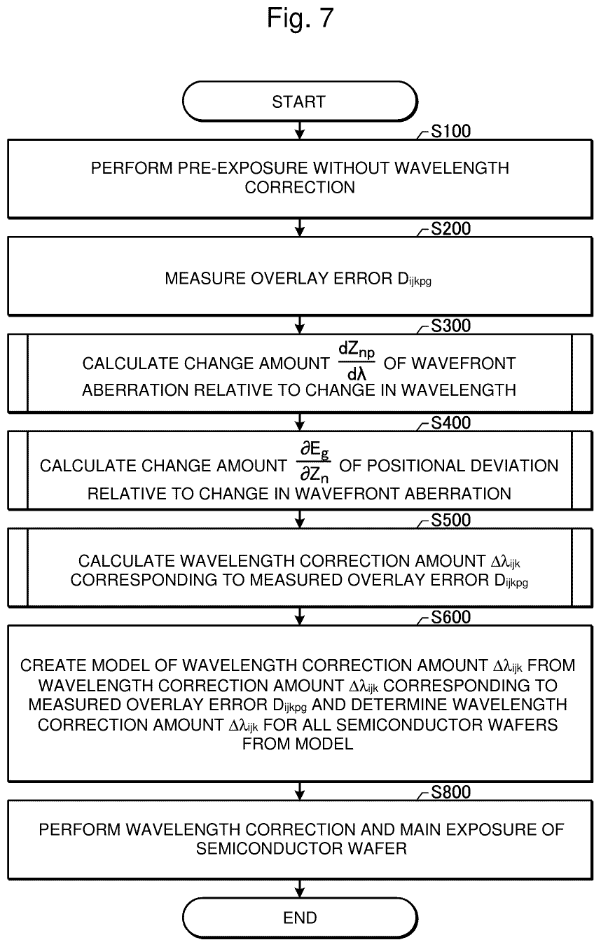

FIG. 7 is a flowchart illustrating processing of wavelength correction by the first embodiment. The lithography control processor 310 determines a wavelength correction amount Δλᵢⱼₖ based on exposure results of pre-exposure and information of the exposure apparatus 200 and the reticle pattern, and performs main exposure by the following processing.

In S100, the lithography control processor 310 transmits signals to the exposure control processor 210 and the laser control processor 130 to perform the pre-exposure without wavelength correction. The pre-exposure is performed by a same exposure sequence as the exposure sequence of the main exposure for manufacturing an electronic device. A semiconductor wafer on which the pre-exposure is performed will be referred to as a pre-exposure wafer hereinafter so as to be distinguished from a semiconductor wafer on which the main exposure is performed.

In S200, the lithography control processor 310 transmits signals to the wafer inspection processor 710 to measure an overlay error D_{ijkpg} of the pre-exposure wafer on which the pre-exposure has been performed. The overlay error D_{ijkpg} is an example of measurement results regarding the positional deviation of the exposure results. Instead of the overlay error D_{ijkpg}, the CD may be measured.

It is not necessary to measure the overlay error D_{ijkpg} for all the pre-exposure wafers on which the pre-exposure has been performed, and it is sufficient to measure it for one or more pre-exposure wafers. It is not necessary to measure the overlay error D_{ijkpg} for all the scan fields SF included in the pre-exposure wafer, and it is sufficient to measure it for two or more scan fields SF.

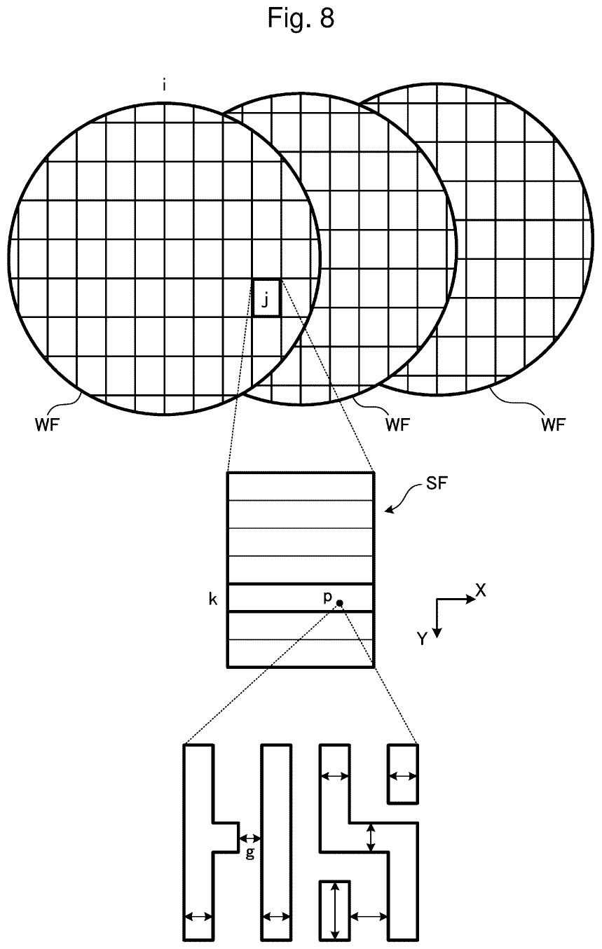

FIG. 8 illustrates an entire pre-exposure wafer WF or semiconductor wafer WF and details of a part thereof. The pre-exposure includes the exposure of a plurality of pre-exposure wafers WF, and the main exposure includes the exposure of a plurality of semiconductor wafers WF. A subscript i specifies one of the pre-exposure wafers WF or one of the semiconductor wafers WF. The subscript i indicates in what order the pre-exposure wafer WF is to be exposed from the start of the pre-exposure, or in what order the semiconductor wafer WF is to be exposed from the start of the main exposure. When referring to the first and second pre-exposure wafers WF, the order of the exposure of the first and second pre-exposure wafers WF is indicated by ordinal numbers, and when referring to the first and second semiconductor wafers WF, the order of the exposure of the first and second semiconductor wafers WF is indicated by ordinal numbers.

One pre-exposure wafer WF or one semiconductor wafer WF includes the scan fields SF. A subscript j specifies one of the scan fields SF. The subscript j indicates in what order the scan field SF is scanned in one pre-exposure wafer WF or one semiconductor wafer WF. First and second scan fields in the present disclosure are the scan fields SF included in the first semiconductor wafer WF. Third and fourth scan fields in the present disclosure are the scan fields SF included in the first pre-exposure wafer WF, where the overlay error D_{ijkpg} is measured. A fifth scan field in the present disclosure is the scan field SF included in the second pre-exposure wafer WF, where the overlay error D_{ijkpg} is measured. Sixth and seventh scan fields in the present disclosure are the scan fields SF included in the second semiconductor wafer WF.

In one scan field SF, a position on a Y axis parallel to a scan direction is defined as an in-field position, and a subscript k specifies one in-field position. The number of in-field positions included in one scan field SF corresponds to the number of models to be described later.

A position in the beam cross section B (see FIG. 3 to FIG. 5) of the pulse laser beam at the position of the workpiece table WT is defined as an in-slit position, and a subscript p specifies one in-slit position.

A measurement point for the positional deviation included in the reticle pattern is called a gauge, and some examples of the gauge are illustrated in FIG. 8 with bidirectional arrows. A subscript g specifies one gauge.

The subscripts i, j, k, p, and g are natural numbers. The overlay error D_{ijkpg} is measured for the scan fields SF, the in-field positions, the in-slit positions, and the gauges. The overlay error D_{ijkpg} is a measured value for which the pre-exposure wafer WF, the scan field SF, the in-field position, the in-slit position, and the gauge as measurement targets are specified by the subscripts i, j, k, p, and g.

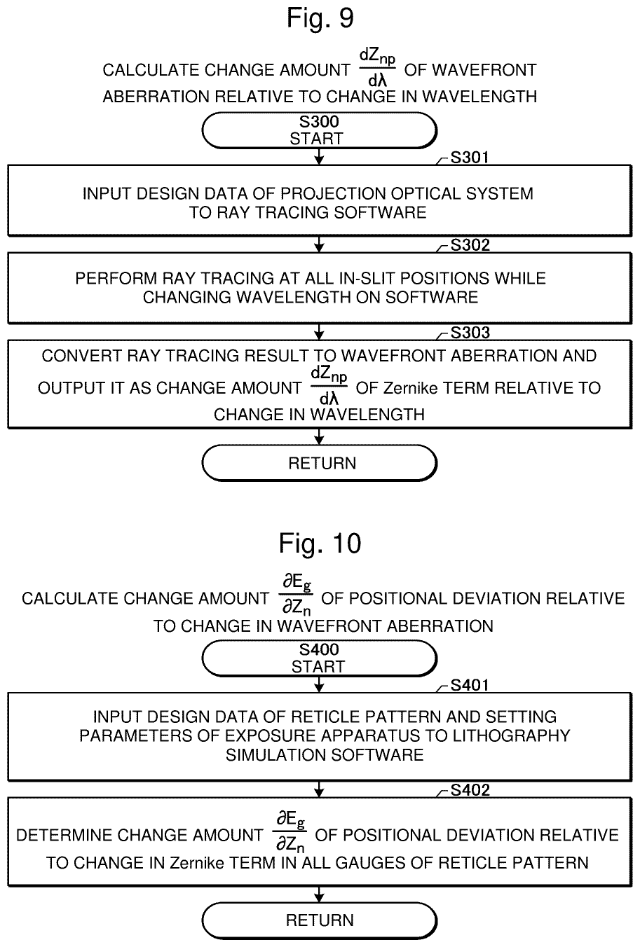

Referring back to FIG. 7, in S300, the lithography control processor 310 calculates a change amount dZₙₚ/dλ of the wavefront aberration W relative to the change in the wavelength. Details of S300 will be described later with reference to FIG. 9. The change amount dZₙₚ/dλ corresponds to a first change amount in the present disclosure.

In S400, the lithography control processor 310 calculates a change amount ∂E_{g}/∂Zₙ of the positional deviation relative to the change in the wavefront aberration W. Details of S400 will be described later with reference to FIG. 10. The processing in S300 and S400 may be performed before S100. The change amount ∂E_{g}/∂Zₙ corresponds to a second change amount in the present disclosure.

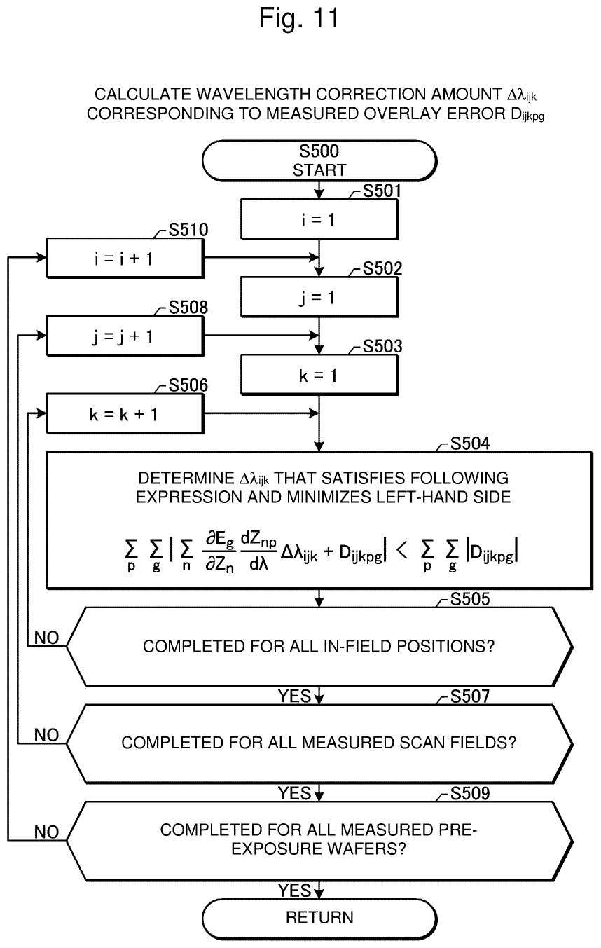

In S500, the lithography control processor 310 calculates the wavelength correction amount Δλᵢⱼₖ corresponding to the measured overlay error D_{ijkpg}. Details of S500 will be described later with reference to FIG. 11.

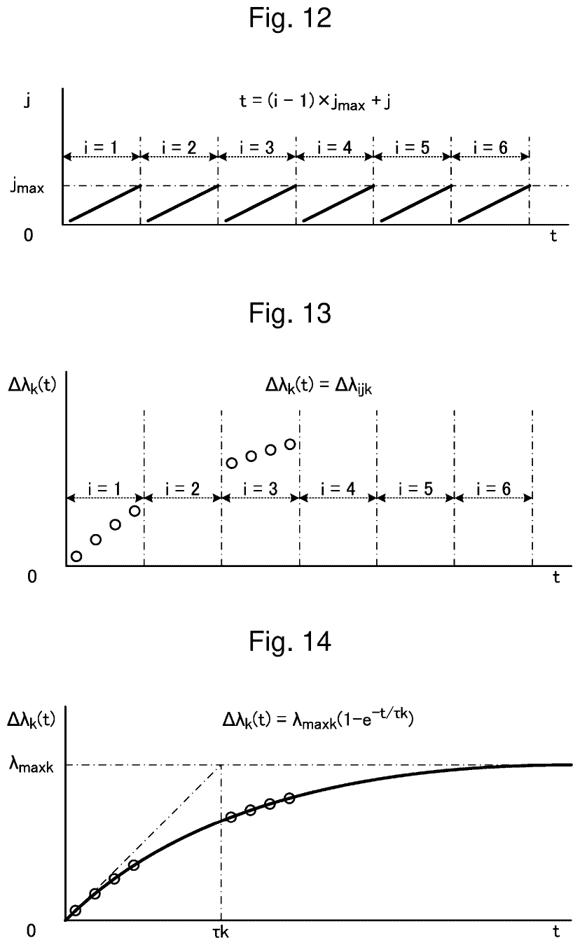

In S600, the lithography control processor 310 creates a model of the wavelength correction amount Δλᵢⱼₖ from the wavelength correction amount Δλᵢⱼₖ corresponding to the measured overlay error D_{ijkpg}, and determines the wavelength correction amount Δλᵢⱼₖ for all the semiconductor wafers WF from the model. Details of S600 will be described later with reference to FIG. 12 to FIG. 16.

In S800, the lithography control processor 310 transmits signals to the exposure control processor 210 and the laser control processor 130 to perform wavelength correction based on the determined wavelength correction amount Δλᵢⱼₖ for the main exposure of the semiconductor wafer WF. By performing the wavelength correction, chromatic aberration can be generated, and the overlay error D_{ijkpg} can be canceled.

After S800, the lithography control processor 310 ends the processing of the present flowchart.

2.2.3 Calculation of dZₙₚ/dλ

FIG. 9 is a flowchart illustrating the details of processing for calculating a change amount dZₙₚ/dλ of the wavefront aberration W relative to the change in wavelength. The processing illustrated in FIG. 9 corresponds to a subroutine of S300 in FIG. 7.

In S301, the lithography control processor 310 inputs design data of the projection optical system 202 to ray tracing software. Examples of ray tracing software include software for optical design and evaluation such as Zemax from ANSYS, Inc. and CODE V from Synopsys, Inc.

In S302, the lithography control processor 310 performs ray tracing at all the in-slit positions on the beam cross section B while changing the wavelength on the software.

In S303, the lithography control processor 310 converts a ray tracing result into the wavefront aberration W and outputs it as the change amount dZₙₚ/dλ of the Zernike term Zₙₚ relative to the change in wavelength λ. Since the change amount dZₙₚ/dλ depends on the in-slit position, the Zernike term Zₙ is subscripted with p.

After S303, the lithography control processor 310 ends the processing of the present flowchart and returns to the processing illustrated in FIG. 7.

2.2.4 Calculation of ∂E_{g}/∂Zₙ

FIG. 10 is a flowchart illustrating the details of the processing for calculating the change amount ∂E_{g}/∂Zₙ of the positional deviation relative to the change in the wavefront aberration W. The processing illustrated in FIG. 10 corresponds to a subroutine of S400 in FIG. 7.

In S401, the lithography control processor 310 inputs the design data of the reticle pattern and setting parameters of the exposure apparatus 200 to lithography simulation software. Examples of the lithography simulation software include Prolith from KLA Corporation, S-litho from Synopsys, Inc., and Hyperlith from Panoramic Technology Inc.

In S402, the lithography control processor 310 determines the change amount ∂E_{g}/∂Zₙ of the positional deviation relative to the change in the Zernike term Zₙ for all the gauges of the reticle pattern. The change amount ∂E_{g}/∂Zₙ is expressed in partial derivatives because a positional deviation error E_{g} is influenced by a plurality of Zernike terms Zₙ.

After S402, the lithography control processor 310 ends the processing of the present flowchart and returns to the processing illustrated in FIG. 7.

2.2.5 Calculation of Wavelength Correction Amount Δλᵢⱼₖ Corresponding to Measured Overlay Error D_{ijkpg}

FIG. 11 is a flowchart illustrating the details of the processing for calculating the wavelength correction amount Δλᵢⱼₖ corresponding to the measured overlay error D_{ijkpg}. The processing illustrated in FIG. 11 corresponds to a subroutine of S500 in FIG. 7.

In S501, S502, and S503, the lithography control processor 310 sets counters i, j, and k specifying the pre-exposure wafer WF, the scan field SF, and the in-field position to 1, respectively. The counters i, j, and k correspond to the subscripts.

In S504, the lithography control processor 310 determines the wavelength correction amount Δλᵢⱼₖ that satisfies a following expression and minimizes a left-hand side.

$${\sum }_{p} {\sum }_{g} \vert {\sum }_{n} \frac{\partial {E}_{g}}{\partial {Z}_{n}} \frac{{dZ}_{np}}{d λ} {Δλ}_{ijk} + {D}_{ijkpg} \vert < {\sum }_{p} {\sum }_{g} \vert {D}_{ijkpg} \vert \qquad [ Expression 1 ]$$

A right-hand side of the above expression is obtained by integrating absolute values of the measured overlay error D_{ijkpg} for all the in-slit positions and all the gauges. The left-hand side is obtained by integrating absolute values of the wavelength-corrected overlay error for all the in-slit positions and all the gauges. To explain the left-hand side in more detail, (∂E_{g}/∂Zₙ) (dZₙₚ/dλ)Δλᵢⱼₖ is the change amount of the positional deviation when the wavelength is changed by Δλᵢⱼₖ, and this value is calculated for each Zernike term, each in-slit position, and each gauge. A value obtained by integrating this value for all the Zernike terms and integrating absolute values of a total with the measured overlay error D_{ijkpg} for all the in-slit positions and all the gauges corresponds to the left-hand side.

In S505, the lithography control processor 310 determines whether or not calculation of the wavelength correction amount Δλᵢⱼₖ has been completed for all the in-field positions. If there are in-field positions for which the wavelength correction amount Δλᵢⱼₖ has not been calculated (S505: NO), the lithography control processor 310 proceeds to S506. If the wavelength correction amount Δλᵢⱼₖ has been calculated for all the in-field positions (S505: YES), the lithography control processor 310 proceeds to S507.

In S506, the lithography control processor 310 increments the counter k that specifies the in-field position by 1 to update k and returns the processing to S504.

In S507, the lithography control processor 310 determines whether or not the calculation of the wavelength correction amount Δλᵢⱼₖ has been completed for all the measured scan fields SF. If there are scan fields SF for which the wavelength correction amount Δλᵢⱼₖ has not been calculated (S507: NO), the lithography control processor 310 proceeds to S508. If the wavelength correction amount Δλᵢⱼₖ has been calculated for all the measured scan fields SF (S507: YES), the lithography control processor 310 proceeds to S509.

In S508, the lithography control processor 310 increments the counter j that specifies the scan field SF by 1 to update j and returns the processing to S503.

In S509, the lithography control processor 310 determines whether or not the calculation of the wavelength correction amount Δλᵢⱼₖ has been completed for all the measured pre-exposure wafers WF. If there are pre-exposure wafers WF for which the wavelength correction amount Δλᵢⱼₖ has not been calculated (S509: NO), the lithography control processor 310 proceeds to S510. If the wavelength correction amount Δλᵢⱼₖ has been calculated for all the measured pre-exposure wafers WF (S509: YES), the lithography control processor 310 ends the processing of the present flowchart and returns to the processing illustrated in FIG. 7.

In S510, the lithography control processor 310 increments the counter i that specifies the pre-exposure wafer WF by 1 to update i and returns the processing to S502.

### 2.2.6 Calculation of Wavelength Correction Amount Δλᵢⱼₖ for all Semiconductor Wafers WF

Referring to FIG. 12 to FIG. 16, the processing for creating a model of the wavelength correction amount Δλᵢⱼₖ and calculating the wavelength correction amount Δλᵢⱼₖ for all the semiconductor wafers WF in S600 in FIG. 7 will be described.

FIG. 12 illustrates a method for converting the subscript i that specifies the semiconductor wafer WF and the subscript j that specifies the scan field SF to the elapsed time t from the exposure start. The number of the scan fields SF included in one semiconductor wafer WF is defined as jmax. As the value of the subscript j that specifies the scan field SF increases, the elapsed time t from the exposure start also increases. The value of the subscript j is reset every time 1 is added to the value of the subscript i that specifies the semiconductor wafer WF, and as the value of the subscript j increases, the elapsed time t from the exposure start also increases further. From this relationship, the subscripts i and j are converted to the elapsed time t using a following equation.

$$t = ( i - 1 ) \times jmax + j$$

FIG. 13 illustrates the subscripts i and j of the wavelength correction amount Δλᵢⱼₖ corresponding to the measured overlay error D_{ijkpg} being converted into the elapsed time t and plotted as the wavelength correction amount Δλk(t). A horizontal axis of FIG. 13 represents the elapsed time t. Small circles in FIG. 13 indicate the wavelength correction amount Δλk(t).

FIG. 14 illustrates an example of a model obtained by fitting the wavelength correction amount Δλk(t) to an exponential function. The temporal change in the positional deviation is thought to correspond to the temperature rise of the reticle and the optical element after the exposure start, and the temperature rise is thought to change more gradually as it approaches a saturation temperature. Therefore, the wavelength correction amount Δλk(t) is fitted to a following function.

$$Δλ k ( t ) = λ maxk ( 1 - {e}^{- t / τ k} )$$

Here, λmaxk is a maximum value of Δλk(t), and τk is a time constant. A model is created by deriving λmaxk and τk. The values of λmaxk and τk can be derived using a least squares method. That is, λmaxk and τk are derived so as to minimize a value obtained by totaling squares of differences between the wavelength correction amount Δλk(t) for which the subscripts i and j of the wavelength correction amount Δλᵢⱼₖ corresponding to the measured overlay error D_{ijkpg} are converted to the elapsed time t and λmaxk(1−e^{-t/τk}) which is the right-hand side of the above equation.

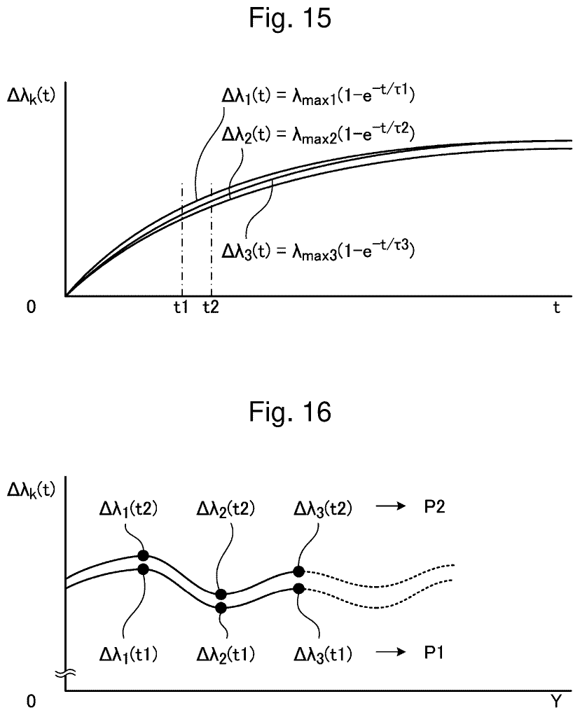

FIG. 15 illustrates examples of a model created for each subscript k. FIG. 15 illustrates the models for cases where the value of k is 1, 2, and 3, respectively. The models correspond to the different in-field positions respectively, and each model indicates the relationship between the elapsed time t from the exposure start and the wavelength correction amount Δλk(t). The reason for creating multiple models is that the temperature of the reticle varies depending on the in-field position and the different wavelength correction amount Δλk(t) is required.

FIG. 16 illustrates examples of a change pattern of the wavelength of the pulse laser beam that scans the scan field SF. A horizontal axis of FIG. 16 indicates a Y-direction position of the scan field SF. Once the semiconductor wafer WF and the scan field SF to be exposed are specified, the elapsed time t can be specified according to FIG. 12 from the corresponding subscripts i and j, and the change pattern of the wavelength of the pulse laser beam can be obtained from the models illustrated in FIG. 15.

For example, if the elapsed time corresponding to the first scan field of the first semiconductor wafer WF is t1, the wavelength correction amounts Δλ1(t1), Δλ2(t1), Δλ3(t1), . . . corresponding to the in-field positions at the elapsed time t1 can be determined from the models in FIG. 15. By determining an approximate curve from the wavelength correction amounts Δλ1(t1), Δλ2(t1), Δλ3(t1), . . . or by performing interpolation processing, the wavelength of a first pulse laser beam that scans the first scan field can be set to a first pattern P1 that changes according to the in-field position.

If the elapsed time corresponding to the second scan field of the first semiconductor wafer WF, which is scanned after the first scan field, is t2, the wavelength correction amounts Δλ1(t2), Δλ2(t2), Δλ3(t2), . . . corresponding to the in-field positions at the elapsed time t2 can be determined from the models in FIG. 15. From these wavelength correction amounts Δλ1(t2), Δλ2(t2), Δλ3(t2), . . . , the wavelength of a second pulse laser beam that scans the second scan field can be set to a second pattern P2 that changes according to the in-field position.

### 2.2.7 Relationship Between Wavelength Fluctuation in Scan Field SF and Wavelength Fluctuation Corresponding to Elapsed Time t

As can be seen from FIG. 15 and the equation for the model, when the elapsed time t is 1, that is, when the first scan field SF of the first semiconductor wafer WF is exposed, the wavelength correction amount Δλk(t) is close to zero. The wavelength at that time is defined as an initial wavelength. As time passes after the exposure start, the absolute value of the wavelength correction amount Δλk(t) increases, so that the absolute value of a difference between the initial wavelength and the subsequent wavelength increases.

Therefore, when a difference between the initial wavelength and an average wavelength of the first pattern P1 is defined as a first average correction amount and a difference between the initial wavelength and an average wavelength of the second pattern P2 is defined as a second average correction amount, an absolute value of the first average correction amount is smaller than an absolute value of the second average correction amount.

However, as can be seen from FIG. 16, a fluctuation range of the wavelength in each of the first and second patterns P1 and P2 may be larger than the difference between the first and second average correction amounts. For example, when scanning the second scan field after the first scan field, the difference between the first and second average correction amounts is small. In that case, when a maximum value of absolute differences between the initial wavelength and the wavelength of the first pattern P1 is defined as a maximum correction amount and a minimum value of absolute differences between the initial wavelength and the wavelength of the second pattern P2 is defined as a minimum correction amount, the maximum correction amount is larger than the minimum correction amount.

Similarly, when exposing the semiconductor wafers WF, the change pattern of the wavelength of the pulse laser beam can be obtained from the models illustrated in FIG. 15. For example, the wavelength of a third pulse laser beam that scans the sixth scan field of the second semiconductor wafer WF, which is exposed after the first semiconductor wafer WF is exposed, can be set to a third pattern that is different from both the first and second patterns P1 and P2. In addition, the wavelength of a fourth pulse laser beam that scans the seventh scan field of the second semiconductor wafer WF can be set to a fourth pattern that is different from the first and second patterns P1 and P2 and the third pattern.

In this case, when the difference between the initial wavelength and the average wavelength of the second pattern P2 is defined as the second average correction amount and a difference between the initial wavelength and an average wavelength of the third pattern is defined as a third average correction amount, the absolute value of the second average correction amount is smaller than the absolute value of the third average correction amount.

However, the fluctuation range of the wavelength in each of the second pattern P2 and the third pattern may be larger than the difference between the second and third average correction amounts. For example, when scanning the sixth scan field after the second scan field, the difference between the second and third average correction amounts is small. In that case, when the maximum value of the absolute differences between the initial wavelength and the wavelength of the second pattern P2 is defined as the maximum correction amount and the minimum value of the absolute differences between the initial wavelength and the wavelength of the third pattern is defined as the minimum correction amount, the maximum correction amount is larger than the minimum correction amount. Note that the relationships between the average correction amounts and the relationships between the maximum and minimum correction amounts described above are just examples, and calculation results may be different from the present examples.

### 2.3 Effect

(1) According to the first embodiment, the exposure method includes following first and second steps.

The first step includes setting the wavelength of the first pulse laser beam that scans the first scan field of the first semiconductor wafer WF to the first pattern P1 that changes according to the in-field position along a scanning direction in the first scan field, and setting the wavelength of the second pulse laser beam that scans the second scan field of the first semiconductor wafer WF to the second pattern P2 that changes according to the in-field position along the scanning direction in the second scan field and that is different from the first pattern P1, based on measurement results regarding the positional deviation of the exposure results by the pre-exposure using the exposure apparatus 200.

The second step includes scanning the first scan field with the first pulse laser beam, and then scanning the second scan field with the second pulse laser beam using the exposure apparatus 200.

Accordingly, even if the reticle thermally expands unevenly in the exposure apparatus 200 or the projection optical system 202 thermally expands in a localized manner, and even if that thermal expansion changes depending on the elapsed time t, the positional deviation of the exposure can be reduced by changing the wavelength for each scan field SF and each in-field position to change the chromatic aberration.

(2) According to the first embodiment, the first step includes setting the wavelengths of the first and second pulse laser beams based on the positional deviation of the exposure results at the in-field positions in the third scan field of the first pre-exposure wafer WF on which the pre-exposure has been performed and the positional deviation of the exposure results at the in-field positions in the fourth scan field of the first pre-exposure wafer WF.

Accordingly, by using the measurement results of the positional deviation for each scan field SF and each in-field position by the pre-exposure, it is possible to set the wavelength so as to appropriately reduce the positional deviation of the exposure.

(3) According to the first embodiment, the first step includes determining the wavelength correction amount Δλᵢⱼₖ corresponding to the time difference of the pre-exposure of the third and fourth scan fields and each of the in-field positions in the third and fourth scan fields based on the first change amount dZₙₚ/dλ obtained based on information of the exposure apparatus 200 as the change amount of the wavefront aberration W relative to the change in the wavelength and the second change amount ∂E_{g}/∂Zₙ obtained based on the information of the exposure apparatus 200 and information of the reticle pattern as the change amount of the positional deviation relative to the change in the wavefront aberration W, and setting the wavelengths of the first and second pulse laser beams based on the wavelength correction amount Δλᵢⱼₖ.

Accordingly, by using the relationship between the change in the wavelength and the change in the positional deviation in addition to the measurement results of the positional deviation, it is possible to set the wavelength so as to appropriately reduce the positional deviation of the exposure.

(4) According to the first embodiment, the first step includes setting the wavelengths of the first and second pulse laser beams based on the positional deviation of the exposure results at the in-field positions in the third scan field of the first pre-exposure wafer WF on which the pre-exposure has been performed and the positional deviation of the exposure results at the in-field positions in the fifth scan field of the second pre-exposure wafer WF on which the pre-exposure has been performed after the first pre-exposure wafer WF.

Accordingly, by pre-exposing the pre-exposure wafers WF, it is possible to improve accuracy of the wavelength correction.

(5) According to the first embodiment, the first step includes determining the wavelength correction amount Δλᵢⱼₖ corresponding to the time difference of the pre-exposure of the third and fifth scan fields and each of the in-field positions in the third and fifth scan fields based on the first change amount dZₙₚ/dλ obtained based on the information of the exposure apparatus 200 as the change amount of the wavefront aberration W relative to the change in the wavelength and the second change amount ∂E_{g}/∂Zₙ obtained based on the information of the exposure apparatus 200 and the information of the reticle pattern as the change amount of the positional deviation relative to the change in the wavefront aberration W, and setting the wavelengths of the first and second pulse laser beams based on the wavelength correction amount Δλᵢⱼₖ.

Accordingly, by using the relationship between the change in the wavelength and the change in the positional deviation in addition to the measurement results of the positional deviation, it is possible to set the wavelength so as to appropriately reduce the positional deviation of the exposure.

(6) According to the first embodiment, the first step includes creating the models corresponding to the different in-field positions, the models each indicating the relationship between the elapsed time t from the exposure start and the wavelength correction amount Δλᵢⱼₖ, and setting the wavelengths of the first and second pulse laser beams based on the models.

Accordingly, by creating the models, even if there are unmeasured parts of the positional deviation of the exposure results, it is possible to appropriately set the wavelength to reduce the positional deviation of the exposure.

(7) According to the first embodiment, the elapsed time t is associated with in what order the first semiconductor wafer WF is to be exposed and in what order the first and second scan fields are to be scanned.

Accordingly, by converting in what order the semiconductor wafer WF is and in what order the scan field SF is to a time axis, the model can be expressed as a function of the elapsed time t.

(8) According to the first embodiment, the first step includes determining the wavelength correction amount Δλᵢⱼₖ corresponding to the time difference of the pre-exposure of the third and fourth scan fields and each of the in-field positions in the third and fourth scan fields based on the positional deviation of the exposure results at the in-field positions in the third scan field of the first pre-exposure wafer WF on which the pre-exposure has been performed, the positional deviation of the exposure results at the in-field positions in the fourth scan field of the first pre-exposure wafer WF, the first change amount dZₙₚ/dλ obtained based on the information of the exposure apparatus 200 as the change amount of the wavefront aberration W relative to the change in the wavelength, and the second change amount ∂E_{g}/∂Zₙ obtained based on the information of the exposure apparatus 200 and the information of the reticle pattern as the change amount of the positional deviation relative to the change in the wavefront aberration W, creating the models based on the wavelength correction amount Δλᵢⱼₖ, and setting the wavelengths of the first and second pulse laser beams based on the models.

Accordingly, by creating the models from the wavelength correction amount Δλᵢⱼₖ corresponding to the time difference of the pre-exposure of the different scan fields SF and each of the in-field positions therein, it is possible to set the wavelength so as to appropriately reduce the positional deviation of the exposure.

(9) According to the first embodiment, the first step includes determining the wavelength correction amount Δλᵢⱼₖ corresponding to the time difference of the pre-exposure of the first and second pre-exposure wafers WF and each of the in-field positions in the first and second pre-exposure wafers based on the positional deviation of the exposure results at the in-field positions in the third scan field of the first pre-exposure wafer WF on which the pre-exposure has been performed, the positional deviation of the exposure results at the in-field positions in the fifth scan field of the second pre-exposure wafer WF on which the pre-exposure has been performed after the first pre-exposure wafer WF, the first change amount dZₙₚ/dλ obtained based on the information of the exposure apparatus 200 as the change amount of the wavefront aberration W relative to the change in the wavelength, and the second change amount ∂E_{g}/∂Zₙ obtained based on the information of the exposure apparatus 200 and the information of the reticle pattern as the change amount of the positional deviation relative to the change in the wavefront aberration W, creating the models based on the wavelength correction amount Δλᵢⱼₖ, and setting the wavelengths of the first and second pulse laser beams based on the models.

Accordingly, by creating the models from the wavelength correction amount Δλᵢⱼₖ corresponding to the time difference of the pre-exposure of the different pre-exposure wafers WF and each of the in-field positions therein, it is possible to set the wavelength so as to appropriately reduce the positional deviation of the exposure.

(10) According to the first embodiment, the first step includes setting the wavelength of the first pulse laser beam to the first pattern P1 by determining the wavelength correction amount Δλᵢⱼₖ corresponding to the first scan field from each of the models, and setting the wavelength of the second pulse laser beam to the second pattern P2 by determining the wavelength correction amount Δλᵢⱼₖ corresponding to the second scan field from each of the models.

Accordingly, by using the models respectively corresponding to the different in-field positions, it is possible to set the pattern of the wavelength that changes depending on the in-field position.

(11) According to the first embodiment, the pre-exposure includes exposing the pre-exposure wafer WF at a constant wavelength.

Accordingly, it is possible to acquire appropriate measurement results while keeping the influence of the wavelength constant.

(12) According to the first embodiment, the absolute value of the first average correction amount that is the difference between the initial wavelength, which is the wavelength of an initial pulse laser beam for irradiating the first semiconductor wafer WF with, and the average wavelength of the first pattern P1 is smaller than the absolute value of the second average correction amount that is the difference between the initial wavelength and the average wavelength of the second pattern P2.

Accordingly, it is possible to increase the average correction amount corresponding to the temperature rise when exposing the scan fields SF.

(13) According to the first embodiment, the maximum correction amount, which is the maximum value of the absolute differences between the initial wavelength and the wavelength of the first pattern P1, is larger than the minimum correction amount, which is the minimum value of the absolute differences between the initial wavelength and the wavelength of the second pattern P2, and the second scan field is scanned after the first scan field in the second step.

Accordingly, by making the change amount of the wavelength within the scan field SF larger than the change amount of the wavelength when moving from one scan field SF to the next, it is possible to appropriately perform the wavelength correction for each in-field position.

(14) According to the first embodiment, the first step includes setting the wavelength of the third pulse laser beam that scans the sixth scan field of the second semiconductor wafer WF exposed after the first semiconductor wafer WF is exposed to the third pattern that changes according to the in-field position along the scanning direction in the sixth scan field and that is different from both the first and second patterns P1 and P2, and setting the wavelength of the fourth pulse laser beam that scans the seventh scan field of the second semiconductor wafer WF to the fourth pattern that changes according to the in-field position along the scanning direction in the seventh scan field and that is different from all of the first to third patterns. The second step includes scanning the sixth scan field with the third pulse laser beam, and then scanning the seventh scan field with the fourth pulse laser beam using the exposure apparatus 200. Then, the absolute value of the second average correction amount that is the difference between the initial wavelength, which is the wavelength of the initial pulse laser beam for irradiating the first semiconductor wafer WF with, and the average wavelength of the second pattern P2 is smaller than the absolute value of the third average correction amount that is the difference between the initial wavelength and the average wavelength of the third pattern.

Accordingly, it is possible to increase the average correction amount corresponding to the temperature rise when exposing the semiconductor wafers WF.

(15) According to the first embodiment, the maximum correction amount, which is the maximum value of the absolute differences between the initial wavelength and the wavelength of the second pattern P2, is larger than the minimum correction amount, which is the minimum value of the absolute differences between the initial wavelength and the wavelength of the third pattern, and the sixth scan field is scanned after the second scan field in the second step.

Accordingly, by making the change amount of the wavelength within the scan field SF larger than the change amount of the wavelength when moving from one semiconductor wafer WF to the next, it is possible to appropriately perform the wavelength correction for each in-field position.

Since the wavelength correction of the present embodiment is based on the measurement results when performing the exposure with a specific reticle pattern, in the case of performing the exposure with a new reticle pattern, it is sufficient to acquire measurement results with the new reticle pattern and to reset a wavelength correction pattern. However, if the reticle pattern does not change even when replacing the reticle, it is not necessary to reset the wavelength correction pattern. Moreover, even when replacing the exposure apparatus 200, if a model number and settings of the exposure apparatus 200 do not change, it is not necessary to reset the wavelength correction pattern.

In other respects, the first embodiment is similar to the comparative example.

### 3. Exposure System that Creates Model of Overlay Error D_{ijkpg}

### 3.1 Operation

### 3.1.1 Main Flow

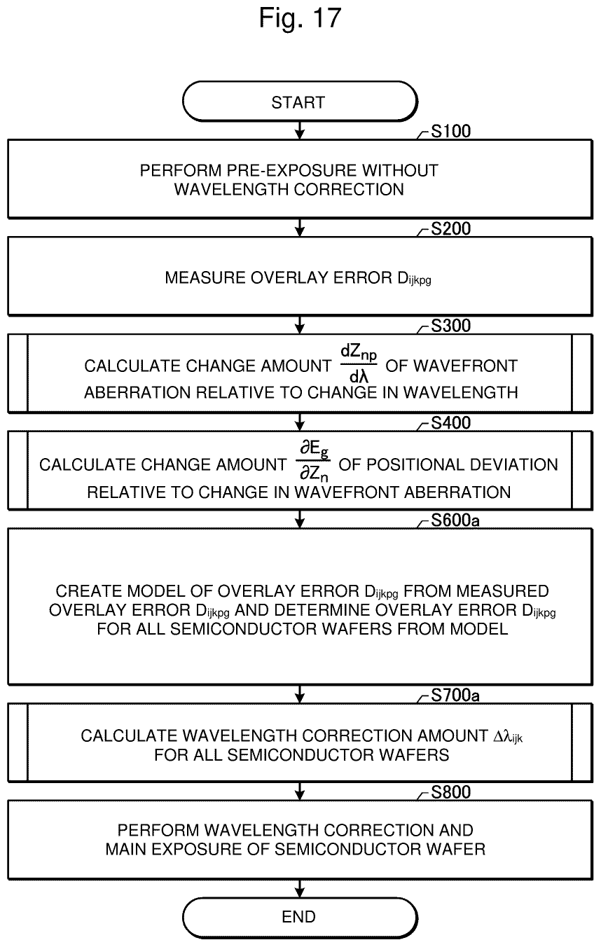

FIG. 17 is a flowchart illustrating the processing of the wavelength correction by a second embodiment. In the second embodiment, instead of S500 and S600 in FIG. 7, the processing in S600a and S700a is performed. The processing in S300 and S400 may be performed between S600a and S700a.

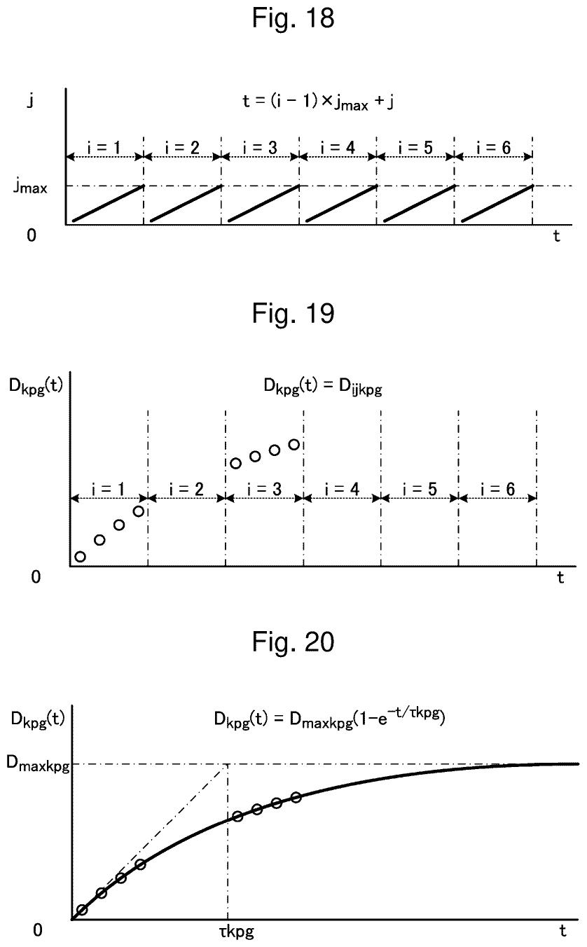

In S600a, the lithography control processor 310 creates a model of the overlay error D_{ijkpg} from the measured overlay error D_{ijkpg} and determines the overlay error D_{ijkpg} for all the semiconductor wafers WF from the model. Details of S600a will be described later with reference to FIG. 18 to FIG. 20.

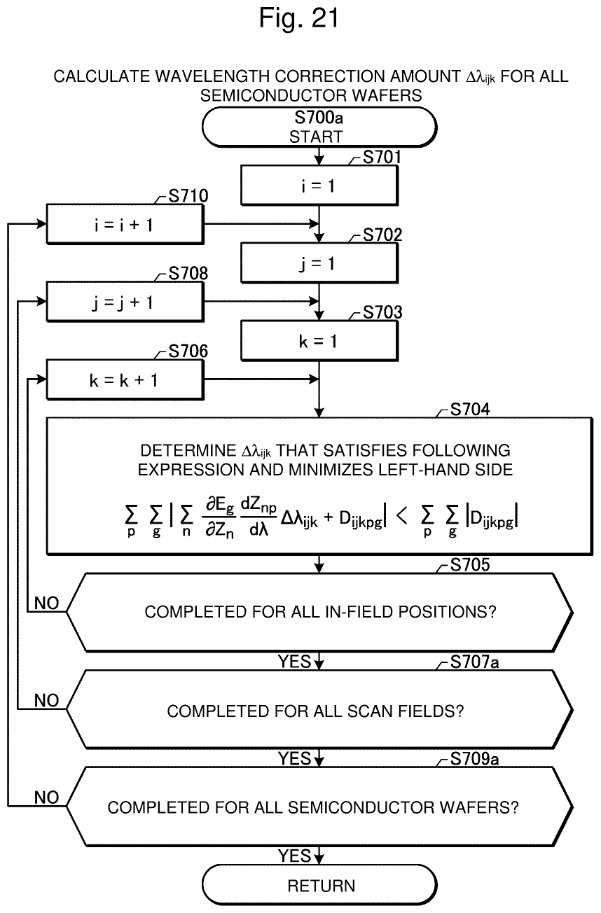

In S700a, the lithography control processor 310 calculates the wavelength correction amount Δλᵢⱼₖ for all semiconductor wafers WF. Details of S700a will be described later with reference to FIG. 21 to FIG. 23.

### 3.1.2 Determination of Overlay Error D_{ijkpg} for all Semiconductor Wafers WF

Referring to FIG. 18 to FIG. 20, the processing for creating a model of the overlay error D_{ijkpg} and determining the overlay error D_{ijkpg} for all the semiconductor wafers WF in S600a in FIG. 17 will be described.

FIG. 18 illustrates the method for converting the subscript i that specifies the semiconductor wafer WF and the subscript j that specifies the scan field SF to the elapsed time t from the exposure start, and its content is similar to that of FIG. 12.

FIG. 19 illustrates the subscripts i and j of the measured overlay error D_{ijkpg} being converted into the elapsed time t and plotted as an overlay error Dkpg(t). A horizontal axis of FIG. 19 represents the elapsed time t. Small circles in FIG. 19 indicate the measured overlay error Dkpg(t).

FIG. 20 illustrates an example of a model obtained by fitting the overlay error Dkpg(t) to a following exponential function.

$$Dkpg ( t ) = Dmaxkpg ( 1 - {e}^{- t / τ kpg} )$$

Here, Dmaxkpg is a maximum value of Dkpg(t), and τkpg is the time constant. A model is created by deriving Dmaxkpg and τkpg. Dmaxkpg and τkpg can be derived using the least squares method. That is, Dmaxkpg and τkpg are derived so as to minimize a value obtained by totaling squares of differences between the overlay error Dkpg(t) for which the subscripts i and j of the measured overlay error D_{ijkpg} are converted to the elapsed time t and Dmaxkpg(1−e^{-t/τkpg}) which is a right-hand side of the above equation.

While the number of the models of the wavelength correction amount Δλk(t) in the first embodiment is the number of the in-field positions included in one scan field SF, more models of the overlay error Dkpg(t) are required in the second embodiment. The number of the models of the overlay error Dkpg(t) is, for example, a product of the number of the in-field positions, the number of the measured in-slit positions, and the number of the measured gauges. The models respectively correspond to combinations of the in-field position, the in-slit position, and the gauge, which are selected from the in-field positions, the in-slit positions, and the gauges that are different from each other, and each model indicates the relationship between the elapsed time t from the exposure start and the overlay error Dkpg(t).

### 3.1.3 Calculation of Wavelength Correction Amount Δλᵢⱼₖ for all Semiconductor Wafers WF

FIG. 21 is a flowchart illustrating the details of the processing for calculating the wavelength correction amount Δλᵢⱼₖ for all the semiconductor wafers WF. The processing illustrated in FIG. 21 corresponds to a subroutine of S700a in FIG. 17.

The processing in S701, S702, S703, S704, S705, S706, S708, and S710 is same as that in S501, S502, S503, S504, S505, S506, S508, and S510 in FIG. 11, respectively. However, the overlay error D_{ijkpg} used in S704 is not the overlay error D_{ijkpg} measured in S200, but is the overlay error D_{ijkpg} determined from the model in S600a. Therefore, in S704, it is possible to determine not only the wavelength correction amount Δλᵢⱼₖ corresponding to the measured overlay error D_{ijkpg}, but also the wavelength correction amount Δλᵢⱼₖ for all the scan fields SF of all the semiconductor wafers WF. S704 is executed more than S504.

In FIG. 21, instead of S507 and S509 in FIG. 11, the processing in S707a and S709a is performed.

In S707a, the lithography control processor 310 determines whether or not the calculation of the wavelength correction amount Δλᵢⱼₖ has been completed for all the scan fields SF. If there are scan fields SF for which the wavelength correction amount Δλᵢⱼₖ has not been calculated (S707a: NO), the lithography control processor 310 proceeds to S708. If the wavelength correction amount Δλᵢⱼₖ has been calculated for all the scan fields SF (S707a: YES), the lithography control processor 310 proceeds to S709a.

In S709a, the lithography control processor 310 determines whether or not the calculation of the wavelength correction amount Δλᵢⱼₖ has been completed for all the semiconductor wafers WF. If there are semiconductor wafers WF for which the wavelength correction amount Δλᵢⱼₖ has not been calculated (S709a: NO), the lithography control processor 310 proceeds to S710. If the wavelength correction amount Δλᵢⱼₖ has been calculated for all the semiconductor wafers WF (S709a: YES), the lithography control processor 310 ends the processing of the present flowchart and returns to the processing illustrated in FIG. 17.

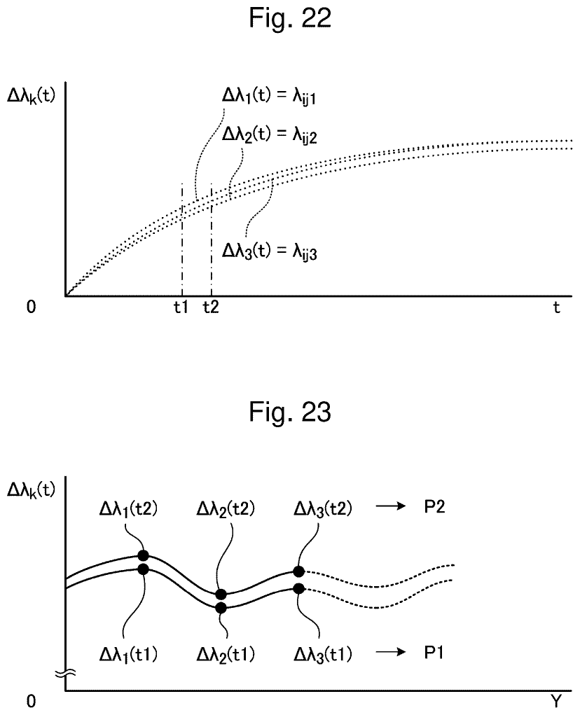

FIG. 22 illustrates examples of the wavelength correction amount Δλᵢⱼₖ determined in S704. The wavelength correction amount Δλᵢⱼₖ determined in S704 is an individual value determined for each semiconductor wafer WF, each scan field SF, and each in-field position, and is not a function of the elapsed time t. However, for the convenience of explanation, the subscripts i and j are converted to the elapsed time t to display Δλk(t).

FIG. 23 illustrates examples of the change pattern of the wavelength of the pulse laser beam that scans the scan field SF. A horizontal axis of FIG. 23 indicates the Y-direction position of the scan field SF.

For example, if the elapsed time corresponding to the first scan field is t1, the wavelength correction amounts Δλ1(t1), Δλ2(t1), Δλ3(t1), . . . corresponding to the in-field positions at the elapsed time t1 can be determined from the wavelength correction amount Δλk(t) illustrated in FIG. 22. By determining an approximate curve from the wavelength correction amounts Δλ1(t1), Δλ2(t1), Δλ3(t1), . . . or by performing interpolation processing, the wavelength of the first pulse laser beam that scans the first scan field can be set to the first pattern P1.

Similarly, if the elapsed time corresponding to the second scan field is t2, the wavelength correction amounts Δλ1(t2), Δλ2(t2), Δλ3(t2), . . . corresponding to the in-field positions at the elapsed time t2 can be determined from the wavelength correction amount Δλk(t) illustrated in FIG. 22, and the wavelength of the second pulse laser beam that scans the second scan field can be set to the second pattern P2.

### 3.2 Effect

(16) According to the second embodiment, the first step includes creating the models corresponding to the different in-field positions, the models each indicating the relationship between the elapsed time t from the exposure start and the positional deviation of the exposure results, and setting the wavelengths of the first and second pulse laser beams based on the models.

Accordingly, by creating the models, even if there are unmeasured parts of the positional deviation of the exposure results, it is possible to reduce the positional deviation of the exposure by appropriately calculating the positional deviation of the exposure results and correcting the wavelength.

(17) According to the second embodiment, the first step includes setting the wavelengths of the first and second pulse laser beams based on the positional deviation determined from each of the models corresponding to the first and second scan fields, the first change amount dZₙₚ/dλ obtained based on the information of the exposure apparatus 200 as the change amount of the wavefront aberration W relative to the change in the wavelength, and the second change amount ∂E_{g}/∂Zₙ obtained based on the information of the exposure apparatus 200 and the information of the reticle pattern as the change amount of the positional deviation relative to the change in the wavefront aberration W.

Accordingly, by using the relationship between the change in the wavelength and the change in the positional deviation in addition to the positional deviation obtained from the model, it is possible to determine the wavelength correction amount Δλᵢⱼₖ for appropriately reducing the positional deviation of the exposure.

(18) According to the second embodiment, the first step includes creating the models based on the positional deviation of the exposure results at the in-field positions in the third scan field of the first pre-exposure wafer WF on which the pre-exposure has been performed and the positional deviation of the exposure results at the in-field positions in the fourth scan field of the first pre-exposure wafer WF.

Accordingly, by taking measurement data of the positional deviation for each scan field SF and each in-field position, it is possible to create an appropriate model that indicates the relationship between the elapsed time t from the exposure start and the positional deviation of the exposure results.

(19) According to the second embodiment, the first step includes creating the models based on the positional deviation of the exposure results at the in-field positions in the third scan field of the first pre-exposure wafer WF on which the pre-exposure has been performed and the positional deviation of the exposure results at the in-field positions in the fifth scan field of the second pre-exposure wafer WF on which the pre-exposure has been performed after the first pre-exposure wafer WF.

Accordingly, by pre-exposing the pre-exposure wafers WF and taking the measurement data of the positional deviation, it is possible to improve the accuracy of the models.

In other respects, the second embodiment is similar to the first embodiment.

### 4. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as “non-limiting terms” unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of “A”, “B”, “C”, “A+B”, “A+C”, “B+C”, and “A+B+C” as well as to include combinations of any thereof and any other than “A”, “B”, and “C”.

What is claimed is:

1. An exposure method comprising:
a first step of
setting a wavelength of a first pulse laser beam that scans a first scan field of a first semiconductor wafer to a first pattern that changes according to an in-field position along a scanning direction in the first scan field, and
setting a wavelength of a second pulse laser beam that scans a second scan field of the first semiconductor wafer to a second pattern that changes according to an in-field position along a scanning direction in the second scan field and that is different from the first pattern,
based on measurement results regarding positional deviation of exposure results by pre-exposure using an exposure apparatus; and
a second step of scanning the first scan field with the first pulse laser beam, and then scanning the second scan field with the second pulse laser beam using the exposure apparatus.

2. The exposure method according to claim 1, wherein
the first step includes
setting the wavelengths of the first and second pulse laser beams, based on
positional deviation of exposure results at a plurality of in-field positions in a third scan field of a first pre-exposure wafer on which the pre-exposure has been performed, and
positional deviation of exposure results at a plurality of in-field positions in a fourth scan field of the first pre-exposure wafer.

3. The exposure method according to claim 2, wherein
the first step further includes:
determining a wavelength correction amount corresponding to a time difference of the pre-exposure of the third and fourth scan fields and each of the in-field positions in the third and fourth scan fields, based on
a first change amount obtained based on information of the exposure apparatus as a change amount of wavefront aberration relative to change in wavelength, and
a second change amount obtained based on the information of the exposure apparatus and information of a reticle pattern as a change amount of positional deviation relative to change in wavefront aberration; and
setting the wavelengths of the first and second pulse laser beams based on the wavelength correction amount.

4. The exposure method according to claim 1, wherein
the first step includes
setting the wavelengths of the first and second pulse laser beams, based on
positional deviation of exposure results at a plurality of in-field positions in a third scan field of a first pre-exposure wafer on which the pre-exposure has been performed, and
positional deviation of exposure results at a plurality of in-field positions in a fifth scan field of a second pre-exposure wafer on which the pre-exposure has been performed after the first pre-exposure wafer.

5. The exposure method according to claim 4, wherein
the first step further includes:
determining a wavelength correction amount corresponding to a time difference of the pre-exposure of the third and fifth scan fields and each of the in-field positions in the third and fifth scan fields, based on
a first change amount obtained based on information of the exposure apparatus as a change amount of wavefront aberration relative to change in wavelength, and
a second change amount obtained based on the information of the exposure apparatus and information of a reticle pattern as a change amount of positional deviation relative to change in wavefront aberration; and
setting the wavelengths of the first and second pulse laser beams based on the wavelength correction amount.

6. The exposure method according to claim 1, wherein
the first step includes creating a plurality of models respectively corresponding to a plurality of different in-field positions, the models each indicating a relationship between elapsed time from exposure start and a wavelength correction amount, and setting the wavelengths of the first and second pulse laser beams based on the models.

7. The exposure method according to claim 6, wherein
the elapsed time is associated with
in what order the first semiconductor wafer is to be exposed, and
in what order the first and second scan fields are to be scanned.

8. The exposure method according to claim 6, wherein
the first step includes:
determining, based on
positional deviation of exposure results at a plurality of in-field positions in the third scan field of a first pre-exposure wafer on which the pre-exposure has been performed,
positional deviation of exposure results at a plurality of in-field positions in the fourth scan field of the first pre-exposure wafer,
a first change amount obtained based on information of the exposure apparatus as a change amount of wavefront aberration relative to change in wavelength, and
a second change amount obtained based on the information of the exposure apparatus and information of a reticle pattern as a change amount of positional deviation relative to change in wavefront aberration,
the wavelength correction amount corresponding to a time difference of the pre-exposure of the third and fourth scan fields and each of the in-field positions in the third and fourth scan fields;
creating the models based on the wavelength correction amount; and
setting the wavelengths of the first and second pulse laser beams based on the models.

9. The exposure method according to claim 6, wherein
the first step includes:
determining, based on
positional deviation of exposure results at a plurality of in-field positions in the third scan field of the first pre-exposure wafer on which the pre-exposure has been performed,
positional deviation of exposure results at a plurality of in-field positions in a fifth scan field of the second pre-exposure wafer on which the pre-exposure has been performed after the first pre-exposure wafer,
a first change amount obtained based on information of the exposure apparatus as a change amount of wavefront aberration relative to change in wavelength, and
a second change amount obtained based on the information of the exposure apparatus and information of a reticle pattern as a change amount of positional deviation relative to change in wavefront aberration
the wavelength correction amount corresponding to a time difference of the pre-exposure of the first and second pre-exposure wafers and each of the in-field positions in the first and second pre-exposure wafers;
creating the models based on the wavelength correction amount; and
setting the wavelengths of the first and second pulse laser beams based on the models.

10. The exposure method according to claim 6, wherein
the first step includes:
setting the wavelength of the first pulse laser beam to the first pattern by determining the wavelength correction amount corresponding to the first scan field from each of the models; and
setting the wavelength of the second pulse laser beam to the second pattern by determining the wavelength correction amount corresponding to the second scan field from each of the models.

11. The exposure method according to claim 1, wherein
the pre-exposure includes exposing a pre-exposure wafer at a constant wavelength.

12. The exposure method according to claim 1, wherein
an absolute value of a first average correction amount that is a difference between an initial wavelength, which is a wavelength of an initial pulse laser beam for irradiating the first semiconductor wafer with, and an average wavelength of the first pattern is smaller than an absolute value of a second average correction amount that is a difference between the initial wavelength and an average wavelength of the second pattern.

13. The exposure method according to claim 12, wherein
a maximum correction amount, which is a maximum value of absolute differences between the initial wavelength and the wavelength of the first pattern, is larger than a minimum correction amount, which is a minimum value of absolute differences between the initial wavelength and the wavelength of the second pattern, and
the second scan field is scanned after the first scan field in the second step.

14. The exposure method according to claim 1, wherein
the first step further includes
setting a wavelength of a third pulse laser beam that scans a sixth scan field of a second semiconductor wafer exposed after the first semiconductor wafer is exposed to a third pattern that changes according to an in-field position along a scanning direction in the sixth scan field and that is different from both the first and second patterns, and
setting a wavelength of a fourth pulse laser beam that scans a seventh scan field of the second semiconductor wafer to a fourth pattern that changes according to an in-field position along a scanning direction in the seventh scan field and that is different from all of the first to third patterns,
the second step further includes scanning the sixth scan field with the third pulse laser beam, and then scanning the seventh scan field with the fourth pulse laser beam using the exposure apparatus, and
an absolute value of a second average correction amount that is a difference between an initial wavelength, which is a wavelength of an initial pulse laser beam with which the first semiconductor wafer with is irradiated, and an average wavelength of the second pattern is smaller than an absolute value of a third average correction amount that is a difference between the initial wavelength and an average wavelength of the third pattern.

15. The exposure method according to claim 14, wherein
a maximum correction amount, which is a maximum value of absolute differences between the initial wavelength and the wavelength of the second pattern, is larger than a minimum correction amount, which is a minimum value of absolute differences between the initial wavelength and the wavelength of the third pattern, and
the sixth scan field is scanned after the second scan field in the second step.

16. The exposure method according to claim 1, wherein
the first step includes creating a plurality of models respectively corresponding to a plurality of different in-field positions, the models each indicating a relationship between elapsed time from exposure start and positional deviation of exposure results, and setting the wavelengths of the first and second pulse laser beams based on the models.

17. The exposure method according to claim 16, wherein
the first step includes
setting the wavelengths of the first and second pulse laser beams, based on
positional deviation determined from each of the models corresponding to the first and second scan fields,
a first change amount obtained based on information of the exposure apparatus as a change amount of wavefront aberration relative to change in wavelength, and
a second change amount obtained based on the information of the exposure apparatus and information of a reticle pattern as a change amount of positional deviation relative to change in wavefront aberration.

18. The exposure method according to claim 16, wherein
the first step includes
creating the models, based on
positional deviation of exposure results at a plurality of in-field positions in a third scan field of a first pre-exposure wafer on which the pre-exposure has been performed, and
positional deviation of exposure results at a plurality of in-field positions in a fourth scan field of the first pre-exposure wafer.

19. The exposure method according to claim 16, wherein
the first step includes
creating the models, based on
positional deviation of exposure results at a plurality of in-field positions in a third scan field of a first pre-exposure wafer on which the pre-exposure has been performed, and
positional deviation of exposure results at a plurality of in-field positions in a fifth scan field of a second pre-exposure wafer on which the pre-exposure has been performed after the first pre-exposure wafer.

20. An electronic device manufacturing method comprising:
a first step of
setting a wavelength of a first pulse laser beam that scans a first scan field of a first semiconductor wafer to a first pattern that changes according to an in-field position along a scanning direction in the first scan field, and
setting a wavelength of a second pulse laser beam that scans a second scan field of the first semiconductor wafer to a second pattern that changes according to an in-field position along a scanning direction in the second scan field and that is different from the first pattern,
based on measurement results regarding positional deviation of exposure results by pre-exposure using an exposure apparatus; and
a second step of scanning the first scan field with the first pulse laser beam, and then scanning the second scan field with the second pulse laser beam using the exposure apparatus, to manufacture an electronic device.
